(19) United States
(12) Patent Application Publication
(10) Pub. No.: US 2006/0255016 A1
(43) Pub. Date: Nov. 16, 2006

(54) Method for polishing copper on a workpiece surface

(75) Inventors: Julia Svirchevski, Santa Clara, CA (US); Saket Chadda, Phoenix, AZ (US); Ismail Emesh, Gilbert, AZ (US); Thomas Laursen, New Haven, CT (US); Bentley Palmer, Chandler, AZ (US); Sanjay Basak, Phoenix, AZ (US); Krishna Murella, Phoenix, AZ (US)

Correspondence Address: INGRASSIA FISHER & LORENZ, P.C., 7150 E. CAMELBACK, STE. 325, SCOTTSDALE, AZ, 85251, US

(73) Assignee: Novellus Systems, Inc.

(21) Appl. No.: 11/489,874

(22) Filed: Jul. 19, 2006

Related U.S. Application Data
(63) Continuation-in-part of application No. 11/117,995, filed on Apr. 29, 2005.
Application No. 11/117,995 is a division of application No. 10/052,010, filed on Jan. 17, 2002, now abandoned.

(51) Int. Cl. C03C 15/00; H01L 21/461

(52) U.S. Cl. 216/88; 438/692

(57) ABSTRACT

A method for polishing a metal layer on a workpiece is provided wherein relative motion is produced between the metal layer and a polishing surface and wherein the metal layer has a polish resistant film thereon. The metal layer is first pre-treated to substantially remove the polish resistant film. Next, the metal layer is polished at low pressure between the metal layer and the polishing surface in the presence of a polishing solution. The pretreating may be accomplished by, for example, sputtering, polishing the polish-resistant film in the presence of abrasive polishing solution, polishing the polish-resistant film at higher pressures between the film and the polishing surface, maintaining the temperature of the pretreating step to be substantially between 10 degrees Centigrade and 30 degrees Centigrade, and chemically removing the film.

### CROSS REFERENCE TO RELATED APPLICATIONS

This is a continuation-in-part of U.S. application Ser. No. 11/117,995 filed on Apr. 29, 2005, which is a divisional of U.S. application Ser. No. 10/052,010 filed on Jan. 17, 2002.

### TECHNICAL FIELD

This invention relates generally to a method for removing conductive material from the surface of a workpiece such as a semiconductor wafer. More particularly, this invention relates to the removal or polishing of the surface of a metal layer on a semiconductor wafer. Still more particularly, this invention relates to a method for removing and/or polishing a polish-resistant surface of a metal layer on a semiconductor wafer which has relative movement with respect to a polishing surface.

### BACKGROUND OF THE INVENTION

Chemical mechanical polishing (CMP) is a technique which has been conventionally used for the planarization or polishing of semiconductor wafers. For example, see U.S. Pat. No. 5,099,614, issued March 1992 to Riarai et al; U.S. Pat. No. 5,329,732 issued July 1994 to Karlsrud et al, and U.S. Pat. No. 5,498,199 issued March 1966 to Karlsrud et al. A typical chemical mechanical polishing apparatus suitable for planarizing a semiconductor surface generally includes a wafer carrier configured to support, guide, and apply pressure to a wafer during the polishing process, a polishing compound such as a slurry (abrasive or non-abrasive) to assist in the removal of material from the surface of the wafer, and a polishing surface such as a polishing pad. A wafer surface is generally polished by moving the surface of the wafer to be polished relative to the polishing surface in the presence of a polishing compound. In particular, the wafer is placed in a carrier such that the surface to be polished is placed in contact with the polishing surface, and the polishing surface and the wafer are moved relative to each other (e.g. rotating, orbiting, etc.) while slurry is supplied to the polishing surface.

Chemical mechanical polishing may also be used to form microelectronic features to provide a substantially smooth, planar surface suitable for subsequent fabrication processes such as photoresist coating and pattern definition. For example, a conductive feature such as a metal line, conductive plug, or the like may be formed on a surface of a wafer by forming trenches and vias on the wafer surface, depositing conductive material over the wafer surface and into the trenches and vias, and removing the conductive material on the surface of the wafer using chemical mechanical polishing, leaving the vias and trenches filled with conductive material. The conductive features often include a barrier material to reduce unwanted diffusion of the conductive material and to promote adhesion between the conductive material and any adjacent layer of the circuit.

Aluminum was often used to form conductive features because its characteristics are compatible with conventional deposition (e.g. chemical vapor deposition) and etch (e.g., reactive ion etch) techniques. While the use of aluminum to form conductive features is adequate in some cases, the use of aluminum in the formation of conductive features becomes increasingly problematic as the size of the conductive features decrease (e.g. less than 0.18 microns). In particular, as the size of a conductive feature decreases, the current density through the feature generally increases, and thus the feature becomes increasingly susceptible to electromigration; i.e., the mass transport of metal due to the flow of current. Electromigration may cause short circuits where the metal accumulates, open circuits where the metal has been depleted, and/or other circuit failures. Similarly, increased conductive feature resistance may cause unwanted device problems such as excess power consumption and heat generation.

Recently, techniques have been developed which utilize copper to form conductive features because copper is less susceptible to electromigration and exhibits a lower resistivity than aluminum. Since copper does not readily form volatile or soluble compounds, the copper conductive features are often formed using damascene. More particularly, the copper conductive features are formed by creating a via within an insulating material, depositing a barrier layer onto the surface of the insulating material and into the via, depositing a seed layer of copper into the barrier layer, electrodepositing a copper layer onto the seed layer to fill the via, and removing any excess barrier metal and copper from the surface of the insulating material using chemical and mechanical polishing.

As stated previously, a CMP apparatus typically includes a wafer carrier configured to hold and transport a wafer during the process of polishing or planarizing the wafer. During the planarizing operation, a pressure applying element (e.g., a rigid plate, a bladder assembly, or the like) that may be an integral part of the wafer carrier, applies pressure such that the wafer engages a polishing surface with a desired amount of force. The carrier and the polishing surface are moved (i.e. rotated, orbited, etc.), typically at different velocities, to cause relative motion between the polishing surface and the wafer and to promote uniform planarization. The polishing surface generally comprises a horizontal polishing pad that may be formed of various materials such as blown polyurethane available commercially from, for example, Rodel Inc. located in Phoenix, Ariz. An abrasive slurry may be applied to the polishing surface which acts to chemically weaken the molecular bonds at the wafer surface so that the mechanical action of the polishing pad and slurry abrasive can remove the undesirable material from the wafer surface.

One example of a CMP apparatus and method based on an orbiting platform is shown and described in U.S. Pat. No. 6,095,904 issued Aug. 1, 2000 and entitled “Orbital Motion Chemical-Mechanical Polishing Method and Apparatus” the teachings of which are herein incorporated by reference. A table or platform having a polishing pad thereon is orbited about an axis. Slurry is fed through a plurality of spaced holes in the polishing pad to distribute slurry across the pad surface during polishing. A semiconductor wafer is pressed face down against the orbiting pad's surface to accomplish the polishing.

An example of a CMP apparatus and method based on a rotating platform is shown and described in U.S. Pat. No. 4,141,180 issued Feb. 27, 1979 and entitled “Polishing Apparatus” the teachings of which are herein incorporated by reference. The polishing apparatus utilizes a pressure head that imparts rotary motion to a wafer to be polished. This polishing head picks up a single, thin, flat semiconductor wafer at a pickup station and transports the wafer to a polishing station which includes a rotatable disk of abrasive material.

Abrasive-free, polishing solutions have been used to polish metallized surfaces on semiconductor wafers. Such polishing solutions typically have less than 1 wt % of polishing abrasives and are formed of oxidizers, such as hydrogen peroxide, which react with the metallized surface to form a removable surface film. Abrasive-free polishing solutions also are formed of agents that render the removable surface film water-soluble. An example of one such polishing solution is disclosed in U.S. Pat. No. 6,117,775, issued to Kondo et al. on Sep. 12, 2000, the teachings of which are herein incorporated by reference. Polishing solutions having less than 1 wt % polishing abrasives have been shown to reduce scratching, dishing and oxide erosion. For convenience, abrasive-free and relatively abrasive-free polishing solutions, such as those having less than 1 wt % polishing abrasives, shall be collectively referred to herein as “abrasive-free polishing solutions.”

Unfortunately, conventional CMP or abrasive free polishing may result in shearing, cracking, and crushing low dielectric-constant materials such as carbon doped or fluorine doped silicon oxide since materials having low dielectric-constants are weaker and more porous. This is of special concern when high polishing pressures and abrasives are employed in the polishing process. Reducing the polishing pressure can alleviate this somewhat; however, this also reduces the rate of material removal.

Thus, a need exists for an improved method of polishing copper metallization surfaces of semiconductor wafers to achieve an acceptable material removal rate without damaging the device structures that include low dielectric constant or otherwise delicate features. A further need exists to achieving acceptable removal rates of copper metallization surfaces at low down-forces.

### BRIEF DESCRIPTION OF THE DRAWINGS

The following drawings are illustrative of particular embodiments of the invention and therefore do not limit the scope of the invention, but are presented to assist in providing a proper understanding of the invention. The drawings are not to scale (unless so stated) and are intended for use in conjunction with the explanations in the following detailed description. The present invention will hereinafter be described in conjunction with the appended drawing figures, wherein like numerals denote like elements, and:

FIG. 1 is a top cutaway view of a first known CMP polishing system;

FIG. 2 is a top cutaway view of a portion of a second known CMP polishing apparatus;

FIG. 3 is a bottom cutaway view of a carousel for use with the apparatus shown in FIG. 2;

FIG. 4 is a top plan view of a typical workpiece carrier for use in conjunction with a polishing apparatus;

FIG. 5 is a top cutaway view of a portion of a third known CMP polishing apparatus;

FIG. 6 is a side cutaway view of a linear belt-type polishing station;

FIG. 7 is a cross-sectional view of an orbital-type polishing station in accordance with an exemplary embodiment of the present invention;

FIG. 8 is a graphical representation illustrating the rate of removal of a copper layer on a wafer as a function of the down-force or pressure between the layer and a polishing surface in a chemical mechanical polishing apparatus utilizing an orbital platform;

FIG. 9 is a graphical representation illustrating the rate of removal of a copper layer on a wafer as a function of pressure between the copper layer and the polishing pad in a chemical mechanical polishing apparatus utilizing a rotating platform;

FIG. 10 is a flow diagram illustrating a method for the chemical mechanical planarization of a metal layer on a work piece, in accordance with an exemplary embodiment of the present invention; and

FIG. 11 is an example of a load cup of a polishing apparatus that may be utilized in accordance with an exemplary embodiment of the present invention.

### DETAILED DESCRIPTION OF EXEMPLARY EMBODIMENTS

The following description is exemplary in nature and is not intended to limit the scope, applicability, or configuration of the invention in any way. Rather, the following description provides a convenient illustration for implementing exemplary embodiments of the invention. Various changes to the described embodiments may be made in the function and arrangement of the elements described herein without departing from the scope of the invention. For example, while various embodiments of the present invention are discussed with reference to removal of a polish resistant film on copper, the present invention also may be used for the removal of oxide layers on other metal layers. In addition, while reference may be made to utilizing various embodiments of the present invention with particular configurations of CMP apparatus, such as orbital or rotational CMP apparatus, it will be understood that the various embodiments of the present invention may be used with any suitable CMP apparatus configuration, including orbital, rotational and linear CMP apparatus.

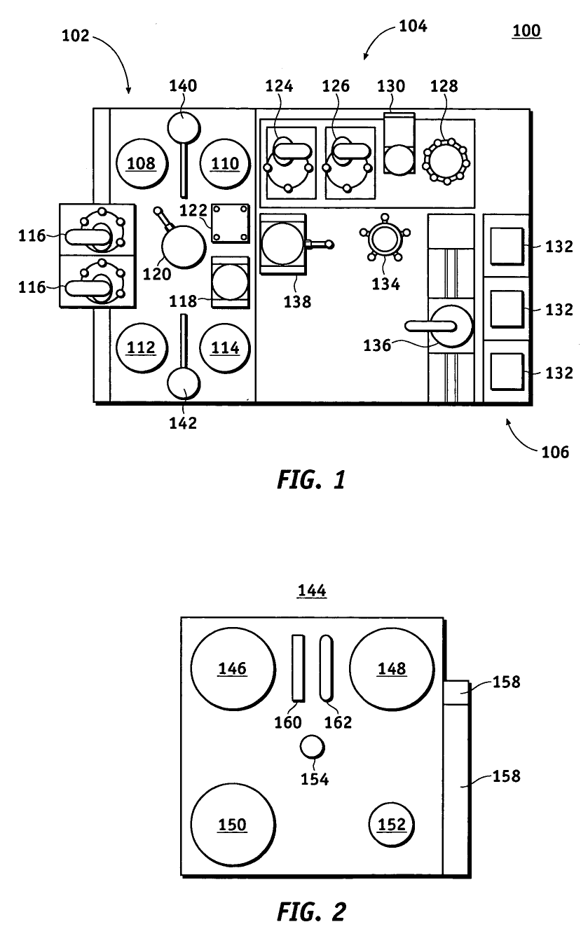

FIG. 1 illustrates a top cutaway view of a polishing apparatus 100, suitable for polishing conductive material on the surface of a workpiece. Apparatus 100 includes a multi-station polishing system 102, a clean system 104, and a wafer load/unload station 106. In addition, apparatus 100 includes a cover (not shown) that surrounds apparatus 100 to isolate apparatus 100 from the surrounding environment. Machine 100 may be an Exceda™ machine available from Novellus Systems, Inc. of San Jose, Calif.

Exemplary polishing station 102 includes four polishing stations, 108, 110, 112, and 114, that each operate independently; a buff station 116; a wet stage 118; a robot 120; and optionally, a metrology station 122. Polishing stations 108-114 may be configured as desired to perform specific functions. Polishing system 102 also includes polishing surface conditioners 140 and 142. The configuration of conditioners 140 and 142 generally depend on the type of polishing surface to be conditioned.

Clean system 104 is generally configured to remove debris such as slurry residue and material from the wafer surface during polishing. In accordance with the illustrated embodiment, system 104 includes clean stations 124 and 126, a spin rinse dryer 128, and a robot 130 configured to transport the wafer between clean stations 124 and 126 and spin rinse dryer 128. Alternatively, clean station 104 may be separate from the remainder of the polishing apparatus. In this case, load station 106 is configured to receive dry wafers for processing, but the wafers may remain in a wet (e.g., deionized water) environment until the wafers are transferred to the clean station. In operation, cassettes 132, including one or more wafers, are loaded onto apparatus 100 at station 106. The wafers are then individually transported to a stage 134 using a dry robot 136. A wet robot 138 retrieves a wafer at stage 132 and transports the wafer to metrology station 122 for film characterization or to stage 118 within polishing system 102. Robot 120 picks up the wafer from metrology station 122 or stage 118 and transports the wafer to one of polishing stations 108-114 for polishing of a conductive material. After a desired amount of material has been removed, the wafer may be transported to another polishing station.

After conductive material has been removed from the wafer surface, the wafer is transferred to buff station 116 to further polish the surface of the wafer. After the polishing and/or buff process, the wafer is transferred to stage 118 which is configured to maintain one or more wafers in a wet (e.g. deionized water) environment.

After the wafer is placed in stage 118, robot 138 picks up the wafer and transports it to clean system 104. In particular, robot 138 transports the wafer to robot 130, which in turn places the wafer in one of the clean stations 124 or 126. The wafer is cleaned using one or more stations 124 and 126 and then is transported to spin rinse dryer 128 to rinse and dry the wafer prior to transporting it to load/unload station 106 using robot 136.

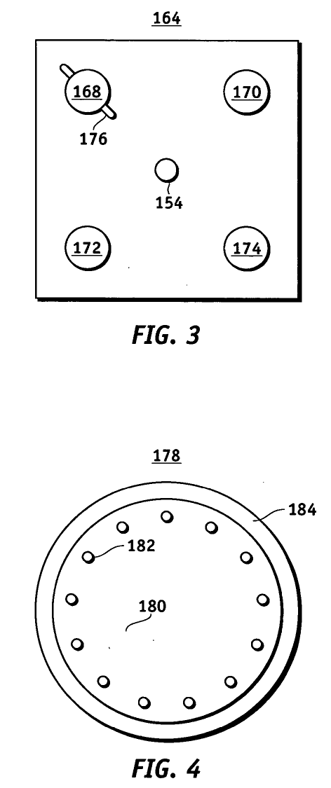

FIG. 2 illustrates a top cut away view of another exemplary polishing apparatus 144, configured to polish the surface of a wafer. Apparatus 144 is suitably coupled to carousel 164 illustrated in FIG. 3 to form an automated polishing system. The system in accordance with this embodiment may also include a removable cover (not shown) overlying apparatus 144 and 164.

Apparatus 144 includes three polishing stations, 146, 148, and 150, a wafer transfer station 152, a center rotational post 154 that is coupled to carousel 164 and which operatively engages carousel 164 to cause it to rotate, a load and unload station 156, and a robot 158 configured to transport wafers between stations 156 and 152. Furthermore, apparatus 144 may include one or more rinse washing stations 116 to rinse and/or wash a surface of a wafer before or after a polishing. Although illustrated with three polishing stations, apparatus 144 may include any desired number of polishing stations, and one or more such polishing stations may be used to buff a surface of a wafer utilizing an abrasive or non-abrasive slurry. Furthermore, apparatus 144 may include an integrated wafer clean and dry system similar to system 104 described above. Wafer station 152 is generally configured to stage wafers before or between polishing and/or buff operations and may be further configured to wash and/or maintain the wafers in a wet environment.

Carousel apparatus 164 includes polishing heads, or carriers, 168, 170, 172, and 174, each configured to hold a single wafer and urge the wafer against the polishing surface (e.g., a polishing surface associated with one of stations 146-150). Each carrier 168-174 is suitably spaced from post 154 such that each carrier aligns with a polishing station or station 152. Each carrier 168-174 is attached to a rotatable drive mechanism which allows carriers 168-174 to cause a wafer to rotate (e.g., during a polishing process). In addition, the carriers may be attached to a carrier motor assembly that is configured to cause the carriers to translate as, for example, along tracks 176. Furthermore, each carrier 168-174 may rotate and translate independently of the other carriers.

In operation, wafers are processed using apparatus 144 and 164 by loading a wafer onto station 152 from station 156 using robot 158. When a desired number of wafers are loaded onto the carriers, at least one of the wafers is placed in contact with the polishing surface. The wafer may be positioned by lowering a carrier to place the wafer surface in contact with the polishing surface, or a portion of the carrier (e.g., a wafer holding surface) may be lowered to position the wafer in contact with the polishing surface. After polishing is complete, one or more conditioners 162 may be employed to condition the polishing surfaces.

During a polishing process, a wafer may be held in place by a carrier 178, illustrated in FIG. 4. Carrier 178 comprises a retaining ring 184 and a receiving plate 180 including one or more apertures 182. Apertures 182 are designed to assist retention of a wafer by carrier 178 by, for example, allowing a vacuum pressure to be applied to the backside of the wafer or by creating enough surface tension to retain the wafer. Retaining ring 184 limits the movement of the wafer during the polishing process.

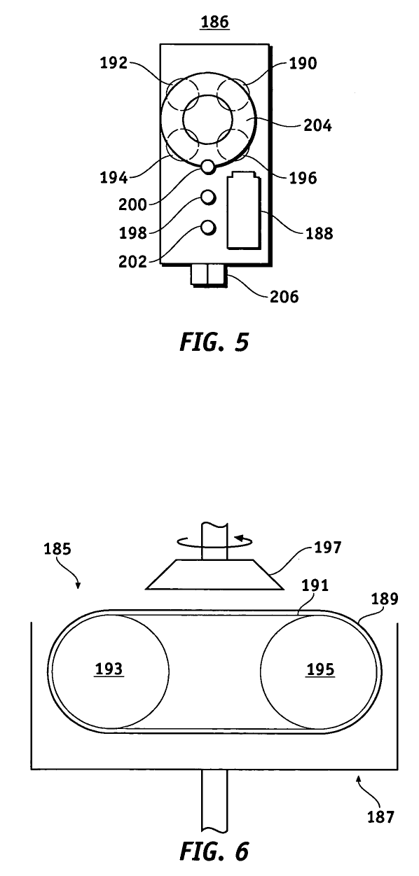

FIG. 5 illustrates another polishing system 186. It is suitably configured to receive a wafer from a cassette 206 and return the wafer to the same or to a predetermined different location within the cassette in a clean common dry state. System 186 includes polishing stations 190 and 192, a buff, or secondary polish station 194, a head loading station 196, a transfer station 198, a wet robot 200, a dry robot 202, a rotatable index table 204, and a clean station 187. Dry robot 202 unloads a wafer from cassette 206 and places the wafer on transfer station 198. The wet robot 200 then transfers the wafer from the transfer station 198 to the head loading station 196. The loading station 196 then operates (raises) to load a wafer into a carrier positioned directly above station 196. The index table then rotates, thereby sequentially moving the wafer to polishing stations 190-194 for polishing and returning to station 196 for unloading by robot 200 and station 198. The wafer is then transferred to clean system 187 to clean, rinse, and dry the wafer before the wafer is returned to cassette 206 using dry robot 202.

Index table 204 releasably holds multiple wafers and travels in one direction to carry each wafer through the complete circuit of processing stations. As alluded to previously, the first and second processing stations along the path of index table 204 are primary wafer polishing devices 190 and 192, preferably linear wafer polishers capable of chemical mechanical planarization. Although linear polishers are preferred, other types of polishing devices, such as rotary polishers may be readily implemented. After the index table transports a wafer to each of the primary wafer polishing devices, index table 204 transports the wafer to secondary polishing station 194, preferably a touchup polishing device such as a rotary buffer. Any of a number of rotary, orbital, or linear touchup polishing devices may be utilized.

Index table 204 operates to convey semiconductor wafers to each processing station so that all semiconductor wafers go through the same processing steps on the same processing station. Index table 204 preferably has a plurality of head receiving areas spaced around the index table and has a central hub connected to a rotating shaft via a motor driven indexer mounted above or below the index table. This configuration permits the index table indexer to form a more compact grouping of processing stations and prevents potential contaminants from dripping down from the index table into the indexer or bearing assembly. Index table 204 is rotatable in precise increments in one direction through continuous 360 degree rotations.

FIG. 6 illustrates a linear polishing apparatus 185 suitable for use in a polishing station. Apparatus 185 includes a lower polishing module 187 including a polishing surface 189 attached to belt 191, rollers 193 and 195, and a carrier 197. To effect polishing, carrier 197 and/or polishing surface 191 move relative to each other. For example, polishing may be effected primarily by moving surface 191 relative to the wafer surface while rotating the wafer about a carrier axis. A linear belt type polishing apparatus can be operated at a higher speed than a large rotating table-type apparatus; e.g. twice to three times as high. For example, a linear belt type polishing apparatus may be operated a speeds of two to three m/s (meters per second), whereas a typical rotational system is limited to about one m/s. The linear belt type system has a similar slurry application scheme to conventional rotating polishing systems; i.e. slurry is introduced onto the belt upstream of the wafer rather than through the belt underneath the wafer.

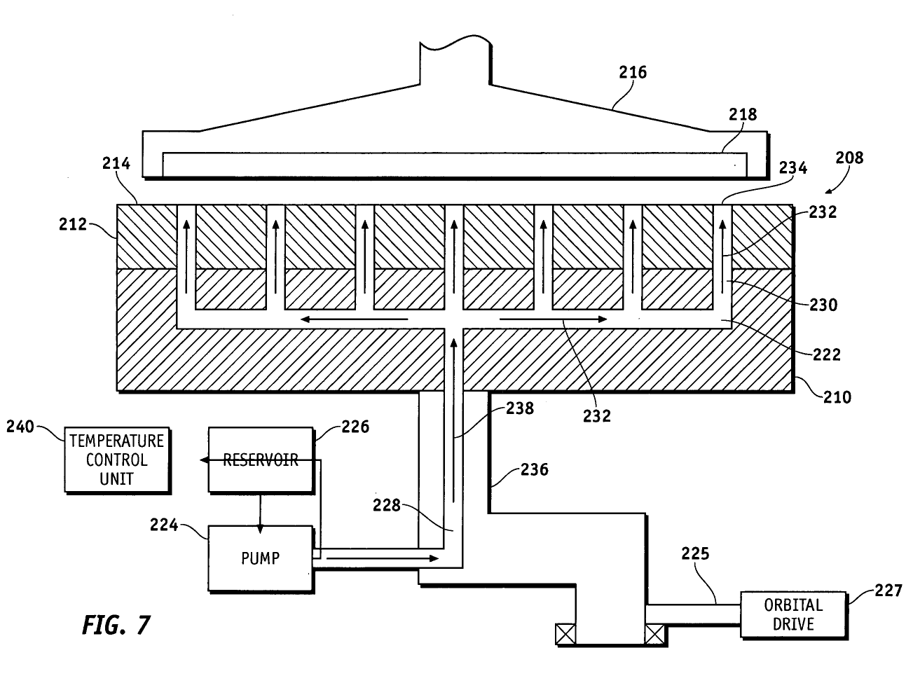

FIG. 7 is a cross-sectional view of a polishing station capable of performing abrasive or abrasive-free polishing. Polishing station 208 is configured to provide uniform and adequate distribution of a polishing solution so that the metallized surface of a subject workpiece can be removed. Polishing station 208 is, in addition, suitable for polishing workpieces having metallized surfaces and copper metallization. Such workpieces include those having single and dual damascenes structures, such as, for example, those having minimum feature dimensions no greater than 0.18 microns. In addition, polishing station 208 is suitable for polishing workpieces incorporating low dielectric-constant materials such as, for example, those materials having a dielectric-constant less than or equal to 2.6.

Polishing station 208 includes a polishing platen 210. A polishing pad 212 having a polishing surface 214 is mounted to platen 210. A wafer carrier 216 holds a workpiece 218, such as a semiconductor wafer, which has a metallized surface. Wafer carrier 216 is configured to press the workpiece against polishing surface 214 while relative motion (e.g. orbital motion) between workpiece 218 and polishing surface 214 is effected. In one embodiment, relative orbital motion between workpiece 218 and polishing surface 214 is created by orbital drive 227 acting upon shaft 236 via pulley belt 225. An example of such an orbital system is shown and described in U.S. Pat. No. 5,554,064 entitled “Orbital Motion Chemical-Mechanical Polishing Apparatus and Method of Fabrication” issued on Sep. 10, 1996 the teachings of which are hereby incorporated by reference.

Carrier 216 may press workpiece 218 against polishing surface 214 with a predetermined down-force so that workpiece 218 experiences down-force pressure against the polishing surface. When workpiece 216 is a semiconductor wafer with a thin film structure formed thereon that includes low dielectric-constant materials, it is desirable that this pressure be limited to a “low-down force” pressure ranging from about 0.1 psi to about 3.0 psi, preferably within a range of from about 0.5 psi to about 2.0 psi.

A polishing solution is delivered to polishing surface 214 of pad 212 by a manifold 222 comprised of a plurality of channels. A pump 224 distributes the solution from reservoir 226 through a fluid line 228 and through distribution manifold 222 to one or more channels 230 formed within platen 210 in a direction indicated by arrows 232. Channels 230 allow for easy transportation of the abrasive-free polishing solution through platen 210. The polishing solution may then suitably flow from channels 230 through one or more openings 234. Platen 210 is coupled to a shaft 236 that is in turn coupled to a drive assembly 227. Polishing station 208 may employ suitable unions (not shown), couplings (not shown) and the like to permit relative movement. Channels 230 permit the polishing solution to flow from openings 234 to pad surface 214. Channels 230 may be molded into pad 212 when originally fabricated or may be machined into pad 212.

It should be clear that while FIG. 7 is described in connection with an orbital-type polishing station incorporating through-the-pad slurry delivery, the invention is equally applicable to a linear belt-type polishing station of the type described above in connection with FIG. 6 or a rotary polishing station of the type shown and described in U.S. patent application Ser. No. 6,213,853 entitled “Integral Machine for Polishing, Cleaning, Rinsing and Drying Workpieces” issued on Apr. 10, 2001 the teachings of which are hereby incorporated by reference.

When using conventional abrasive slurries, the rate of removal of the metallized surface from the wafer at steady state may be characterized by Preston's Law:
RR=k(Pressure)(Velocity)
for a given polishing solution, where “RR” is the rate of removal of the metallized surface, “Pressure” is the pressure or down-force applied to the metallized surface by the polishing surface, “Velocity” is the velocity at which the wafer moves relative to the polishing surface, and “k” is Preston's constant. Thus, if the polishing solution composition and distribution and velocity remain constant, rate of removal will be approximately linear and proportional to the pressure.

It has been found that the use of non-abrasive slurries and low down-force in a CMP apparatus utilizing an orbital platform yields a substantially Prestonian relationship between removal-rate and down-force, and the removal rate is good even at low down-force pressure (0.1 psi to 3.0 psi). Note that the term “orbital platform’ as used herein refers generally to the orbital-type polishing station of FIG. 6 utilizing small orbital or oscillatory motion of the polishing pad combined with through-the-pad slurry delivery; whereas the term “non-orbital platform” as used herein refers to all other types of polishing stations including rotational and linear belt type polishing stations. However, it has also been found that such is not the case when a non-orbital platform is employed. That is, there is very little removal below 3 psi down-force. Between 3 psi and 4 psi, the removal of material begins and increases very rapidly with increasing down-force. The relationship between removal-rate and down-force when utilizing a rotational platform is not linear or Prestonian and, due to the very rapid increase in removal-rate with small increases in down-force, the process is difficult to control.

The behavior exhibited by non-orbital platforms in this regard is believed to be due to the existence of a film which forms on the surface of the metal and is possessed of characteristics which make it more difficult to polish than the metal. The creation of this film may be due to oxidation, subjection to semiconductor processes, exposure to high temperatures, etc. The abrupt relationship between removal rate and down-force is believed to be due to the time it takes non-orbital systems to break through this film. After breakthrough is achieved, relatively small increases in down-force result in significant increases in removal rate.

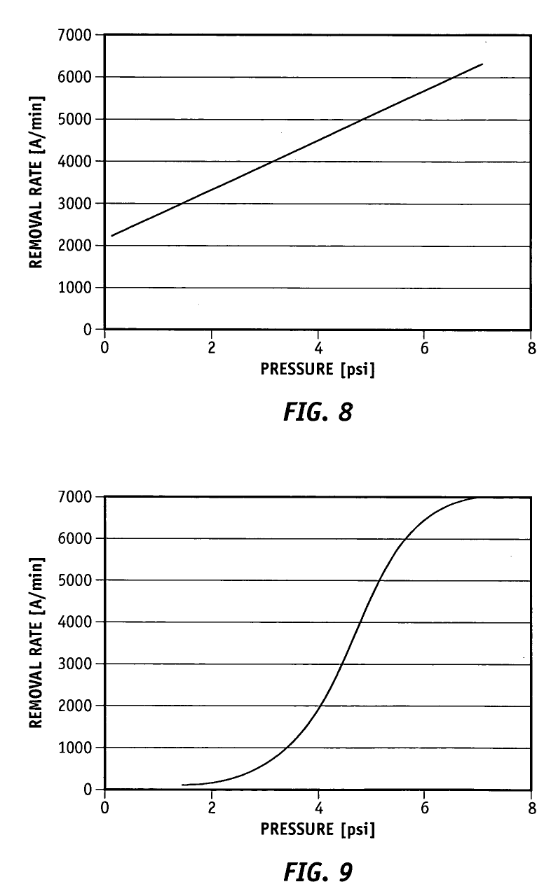

FIG. 8 is a graphical representation illustrating the rate of removal of a metal layer (e.g. copper) on a wafer as a function of the down-force or pressure between the wafer and a polishing surface in a polishing apparatus utilizing an orbital platform; i.e. relative orbital motion is provided between the polishing surface on the pad and the layer surface being polished and slurry is delivered through the pad. As can be seen, the removal rate increases in a substantially linear, Prestonian-like fashion with increasing pressure. This is true over a wide range of down-force; i.e. approximately one psi to over six psi. Thus, the process is highly controllable. As can be seen, acceptable removal rates in the neighborhood of 2000 Angstroms per minute to almost 4000 Angstroms per minute are obtainable in the pressure range from 0.1 psi to 3.0 psi, and this includes removal of the above referred to polish-resistant film which forms on the copper surface.

In contrast, FIG. 9 is a graphical representation illustrating the rate of removal of a metal layer (e.g. copper) on a wafer as a function of pressure between the wafer and the polishing pad in a polishing apparatus that utilizes a conventional rotating platform; i.e. relative motion between the polishing pad and the wafer surface being polished is primarily generated by rotation of the polish pad. As can be seen, the function, in this case, is non-linear/non-Prestonian with very unacceptable removal rates at low pressures. The removal rate is not proportional to the applied pressure, and as a result, the removal rate in a rotating platform machine is far less than that in an orbital platform machine below approximately 4 psi.

It was discovered that the removal-rate/down-force relationship described above in connection with non-orbital platforms is due to the existence of the above described polish-resistant film which forms on the surface of the metal (i.e. the film has characteristics that make it more difficult to polish than the metal) and that the removal-rate/down-force relationship is due to the time it takes the rotational systems to break through this polish resistant film. After breakthrough, relatively small increases in down-force result in very significant increases in removal rate as shown in FIG. 9.

It was also discovered that if the wafer is pretreated to remove the polish-resistant film, Prestonian-like removal of the metal layer can be achieved in rotational systems. This can be accomplished by (1) initiating the polishing process using an abrasive slurry to remove the polish-resistant film and then switching to a non-abrasive slurry; (2) initiating the polishing apparatus using a higher pressure (down-force) or higher relative velocity to remove the film and then switching to a lower pressure or lower velocity; (3) performing the polishing process at a higher temperature, perhaps in conjunction with (1) or (2) above; (4) physically removing the film using techniques such as argon sputtering, or (5) chemically stripping or removing the film. Each of these approaches will be discussed below.

As stated above, one approach to achieving substantially linear or Prestonian-like polishing in a polishing apparatus utilizing a non-orbital type platform is to first remove the surface film utilizing an abrasive slurry (e.g. of the type manufactured by Cabot Microelectronics of Aurora, Ill. and identified by product numbers 5001 and 5003) followed by continued polishing utilizing a non-abrasive slurry such as the type manufactured by Hitachi and identified as 430-TU. Abrasive polishing could take place at a pressure or down-force of, for example, 1.5 psi. This would achieve removal rates in the neighborhood of 2000 Angstroms per minute.

The polishing apparatus shown in FIG. 1 includes four polishing stations 108, 110, 112, and 114 each of which operate independently, the polishing apparatus shown in FIG. 2 includes three polishing stations 146, 148, and 150, and the polishing apparatus shown in FIG. 5 includes polishing stations 190 and 192. Thus, one polishing station in each of the above described machines could be dedicated to polishing the copper layer on a wafer using an abrasive slurry followed by transferring the wafer to a second one of the polishing stations in each apparatus for further polishing using a non-abrasive slurry.

The second solution described above includes initiating the polishing process using a high pressure or down-force, or high relative velocity, followed by further polishing using a low down-force or reduced relative velocity. It has been found that satisfactory results (i.e. substantially linear or Prestonian-like polishing) can be achieved using an initial down-force within the range of 3 to 10 psi (preferably 5-6 psi) for 1 to 20 seconds. This polishing step is followed by further polishing at a lower down-force of 0.1 to 3.0 psi (preferably 0.5-2.0 psi). The duration of this subsequent polishing step depends on the thickness of the copper metallization. Similarly, satisfactory results can be achieved by polishing with a high initial polish pad velocity for about 1 to 20 seconds, followed by a lower polish pad velocity polish. The initial high pad velocity is preferably two to three times the subsequent lower pad velocity required to achieve a particular desired removal rate. For example, if a pad velocity of one m/s is suitable for a particular removal rate of copper, an initial pad velocity of two to three m/s could be used to remove the polish resistant film. These steps could be accomplished on the same polishing machine, or on separate and distinct polishing machines. In the case of a single machine, the initial high-pressure polishing and the subsequent lower pressure polish can both take place on the-same polish station, or, in the case of the polishing machines shown in FIGS. 1, 2, and 5, the initial high-pressure polishing could take place at a first polishing station followed by low pressure polishing at a second station.

Removal of the polish-resistant film may be facilitated by regulating the temperature of the environment in which the polishing takes place. For example, the polishing solution may be heated before being delivered to manifold 222 shown in FIG. 7. Alternatively, the temperature may be increased by providing a heated fluid to the backside of the workpiece. U.S. Pat. No. 5,606,488 issued to Ohashi et al. on Feb. 25, 1997, which patent is hereby incorporated by reference, shows and describes an apparatus configured to regulate the polishing rate of a wafer utilizing backside fluid exposure.

The temperature of the polishing process may be regulated by providing a heat conductive platen configured to be temperature controlled by a heat exchanged fluid circulating therethrough. Alternatively, a solid-state (no fluid) heat exchanger could be utilized to control the temperature of the process apart from the platen. Referring again to FIG. 6, a temperature control unit 240 is provided to heat the solution contained in reservoir 226. For example, the solution may be maintained at a temperature between 10 and 30 degrees Centigrade.

The polish-resistant film may alternatively be removed by a physical cleaning process such as argon sputtering. Sputtering systems most often employ two electrodes and an inert sputtering gas, usually argon. If an argon ion strikes the surfaces of the copper film with sufficient energy, atoms or clusters of atoms will be dislodged or sputtered away from the surface. For example, in a DC sputtering system, voltage is applied across two electrodes which ionize the argon. Sputtering takes place in a chamber that is first evacuated and then filled with a continuous flow of argon. Other physical cleaning techniques may be employed such as selective etching to remove the polish-resistant film. Such techniques are well known, and the interested reader is directed to Introduction to Integrated Circuit Engineering by D. K. Reinhard, Houghton Mifflin Company, Boston, 1987.

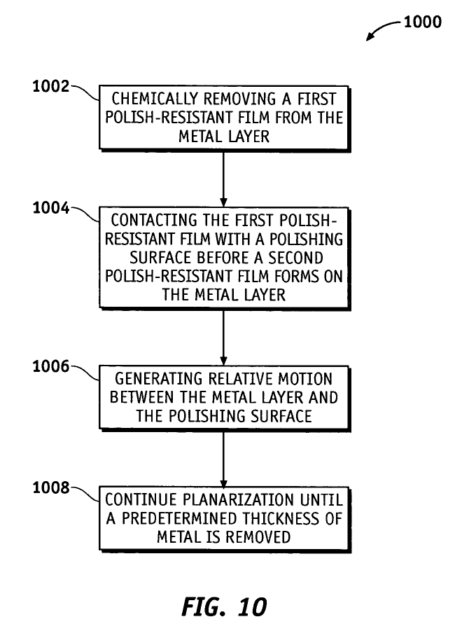

The polish-resistant film may also be chemically stripped or otherwise removed from the substrate copper using a suitable dissolution solution. Turning now to FIG. 10, in accordance with an exemplary embodiment of the present invention, a method 1000 for the chemical mechanical planarization of a metal layer on a wafer begins by chemically removing, at least substantially, a polish-resistant film that has formed on the surface of the metal layer (step 1002). The metal layer may be formed of any suitable metal that may be planarized by a CMP process. Examples of such metals include copper, aluminum, tungsten, cobalt, tantalum, tantalum nitride, titanium, titanium nitride, silver, gold, and ruthenium. The polish-resistant film to be removed from the metal layer thus may comprise any oxide that forms on the metal layer by exposure to air, oxygen, water, or any other oxygen-containing compound. The polish-resistant film may form during storage of the wafer, during a previous processing step, during exposure to water or water vapor, or the like. The thickness of the polish-resistant film typically is significantly less than the thickness of the metal layer. For example, for a metal layer having a thickness of about 6,000 Angstroms to about 11,000 Angstroms, a polish-resistant film layer formed thereon may have a thickness of about 10 to about 100 Angstroms. However, it will be appreciated that the present invention is not limited to removing polish-resistant films in this thickness range and may be used to remove polish-resistant film films of any suitable thickness from a metal layer.

The polish-resistant film is chemically removed from the metal layer by applying to the wafer front surface a fluid that is capable of dissolution of the polish-resistant film upon contact therewith. In one embodiment of the invention, the dissolution fluid may be capable of dissolution of the polish-resistant film and metal from the metal layer. The fluid may be a gas or vapor but preferably is a liquid. Because the fluid may contact polishing apparatus 100 during planarization, it also is preferable that the fluid is not corrosive to the components of polishing apparatus 100. Examples of fluids that are suitable for removing a polish-resistant film from a metal layer of a wafer but that are not typically corrosive to components of a polishing apparatus include dilute inorganic acids, such as sulfuric acid, nitric acid, and phosphoric acid; or organic acids, such as malonic acid, oxalic acid, and citric acid. Preferably, the dissolution fluid is a solution comprising about 1% to about 10% oxalic acid.

The fluid may be applied to the front surface of the wafer in any suitable fashion that permits the fluid to contact the entire surface of the polish-resistant film so that the polish-resistant film can be removed substantially evenly. In one embodiment the wafer may be dipped in a vessel containing the dissolution fluid, and left submersed for a sufficient time to remove substantially all of the polish resistant film, followed by conventional abrasive or abrasive-free polishing of the metal. In another embodiment, the wafer may be polished on a CMP polish station initially in the presence of the dissolution fluid to remove the resistant layer, followed by CMP of the underlying metal using conventional abrasive or abrasive-free slurry. The fluid also may be spin-rinsed onto the wafer. In a preferred embodiment of the invention, the fluid is sprayed onto the wafer in a manner that permits a continuous film to deposit on the polish-resistant film.

In an exemplary embodiment of the invention, the fluid may be applied to the surface of the wafer in sufficient volume so that the fluid continues to cover the wafer surface until the wafer surface contacts a polishing surface, as discussed in more detail below. In this manner, after removal of the polish-resistant film by the fluid, the fluid prevents re-oxidation of the metal layer, thus preventing a significant thickness of a second, subsequent, polish-resistant film layer from forming on the metal layer before the CMP process begins. As used herein, the term “significant thickness” of a second polish-resistant film layer means a thickness greater than about 15 angstroms. In another exemplary embodiment of the invention, the re-oxidation of the metal layer may be sufficiently slow so that it is not necessary for the fluid to remain on the metal layer until the wafer surface contacts a polishing surface. In one exemplary embodiment of the invention, the fluid may be applied to the wafer using an apparatus or device outside of the polishing apparatus 100. For example, the wafer may be dipped in the fluid at a stand-alone pretreatment station and then transported to polishing apparatus 100 for polishing. In another, preferred, embodiment of the invention, the fluid is applied to the wafer by a device or mechanism within polishing apparatus 100. In this regard, the time between application of the fluid and commencement of the CMP process can be shortened, thus minimizing the time during which a subsequent polish-resistant film layer may form. For example, the fluid may be sprayed onto the wafer by sprayers located in a pass-through, pre-treatment stage, a loading stage, a carrier, or in cleaner stations of polishing apparatus 100.

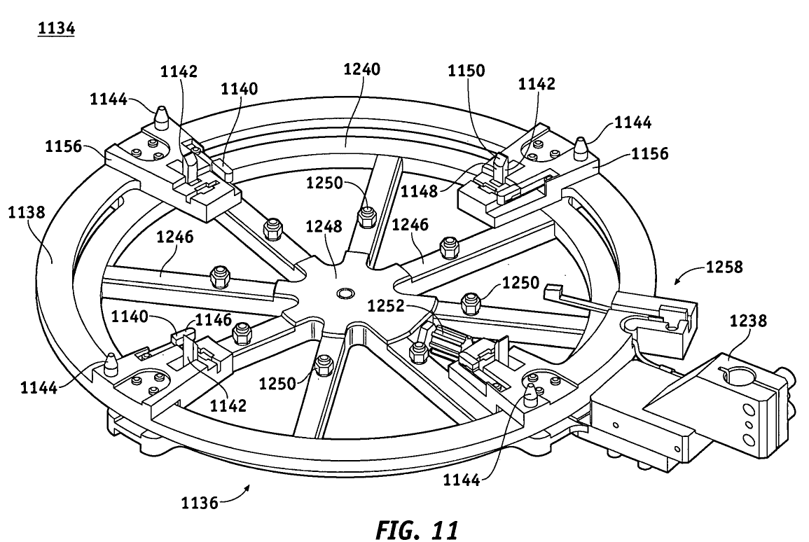

In another, more preferred, exemplary embodiment, the fluid is sprayed onto the wafer surface by sprayers located in a loading cup. The loading cup may be coupled to polishing apparatus 100 and is typically used to load wafers onto wafer carriers. An example of a load cup 1134 having sprayers 1250 that may be used in accordance with embodiments of the present invention is illustrated in FIG. 11. Load cup 1134 includes a wafer platform 1136, which includes a substantially planar peripheral load ring 1138 to which are coupled a plurality of spaced apart lift fingers 1140 and a plurality of spaced apart guide fingers 1142. Load cup 1134 also includes a plurality of spaced apart guide posts 1144. In FIG. 11, load cup 1134 includes four lift fingers, four guide fingers, and four guide posts, but a greater or lesser number could also be used depending on the particular application.

Lift fingers 1140 are designed to support a wafer such as a semiconductor wafer in a position above the plane of peripheral load ring 1138. The lift fingers are positioned about the peripheral load ring along a circular path having a diameter slightly less than the diameter of the wafer to be handled by the load cup. For example, for a 300 mm diameter semiconductor wafer, the lift fingers are positioned along a circular path having a diameter of about 298 mm so that they contact only the outer 1 mm of the wafer. The lift fingers 1140 preferably have an upper surface 1146 that slopes downwardly and inwardly with respect to the circumference of the peripheral load ring 1138. The downwardly sloping surface of the lift fingers helps to insure that even if a wafer is initially misaligned with respect to the load cup mechanism, only the near peripheral edge of the wafer is contacted.

Guide fingers 1142 act to position, preferably to center, a wafer on the load cup mechanism. The plurality of guide fingers 1142 is positioned about the peripheral load ring 1138 along a circular path having a diameter slightly greater than the diameter of the wafer to be handled by the load cup mechanism. For example, if the wafer is a 300 mm semiconductor wafer, vertical surfaces 1148 of the guide fingers 1142 can be placed along a circular path having a diameter of about 300.6 mm. As a wafer is transferred to the load cup mechanism, it is captured by vertical surfaces 1148 of the guide fingers. If a wafer is slightly off center as it is transferred to the load cup mechanism, beveled edges 1150 of the guide fingers guide the wafer to a centered position defined by vertical surfaces 1148. A wafer transferred to load cup mechanism 1134 thus rests with its peripheral edge supported on lift fingers 1140 and centered by vertical surfaces 1148 of guide fingers 142.

Guide posts 1144 are also coupled to peripheral load ring 1138. The guide posts serve to align the load cup mechanism to the processing apparatus such as a CMP carrier head. Preferably one each of a guide post 1144, lift finger 1140, and guide finger 1142 are positioned in proximity to each other. Preferably one each of the guide post, lift finger and guide finger are coupled together by a load/unload block 1156 which, in turn, can be coupled to the peripheral load ring. The load/unload block can be coupled to the peripheral load ring, for example, by screw fasteners or the like.

As illustrated, a load cup arm 1238 is coupled to a support ring 1240. Support ring 1240, in turn, is coupled to and supports peripheral load ring 1138. In a preferred embodiment, a plurality of radial spokes 1246 is coupled at one end to support ring 1240 and at the opposite end to a central hub 1248. The load cup mechanism is provided with a plurality of fluid spray nozzles 1250 from which the fluid can be uniformly sprayed onto the front surface of the wafer before processing. In accordance with one embodiment of the invention, the fluid spray nozzles are positioned on radial spokes 1246 and the spokes are configured as a spray manifold for conveying the fluid to spray nozzles 1250. A fluid coupling 1252 can be fitted to the spray manifold through which fluid can be brought from a fluid reservoir and tubing (not illustrated) to the manifold. It will be appreciated that load cup 1134 of FIG. 11 is just one example of a load cup that may be utilized to apply the fluid to a wafer surface and any other suitable loading cup design comprising sprayers may be used.

Referring again to FIG. 10, after the fluid is applied to the surface of the wafer, it is permitted to remain for a time that is sufficient to permit removal of substantially all the polish-resistant film. Again, however, the time between application of the fluid and commencement of the polishing process is not long enough to permit a significant thickness of a second, subsequent polish-resistant film to form on the metal layer. In addition, the time between application of the fluid and commencement of the polishing process should not be so long that throughput is adversely affected. In an exemplary embodiment of the invention, the time between application of the fluid and commencement of the polishing process is in the range of about 5 to about 60 seconds, preferably in the range of about 5 to about 30 seconds, and more preferably about 5 to about 10 seconds.

In another, optional, exemplary embodiment of the invention, the fluid is heated before being applied to the polish-resistant film on the wafer. Heating the fluid results in an improved rate of reaction between the fluid and the polish-resistant film, thus shortening the amount of time the fluid must remain on the polish-resistant film to remove it from the metal layer. This in turn increases wafer throughput. In an exemplary embodiment, the fluid is heated to a temperature in the range of about 25° C. to about 70° C. In a preferred embodiment of the invention, the fluid is heated to a temperature in the range of about 30° C. to about 50° C.

In another, optional, exemplary embodiment of the invention, the fluid may be removed from the surface of the wafer before the wafer surface is contacted with the polishing surface. The fluid may be removed from the wafer by rinsing the wafer surface with a non-reactive rinse fluid, such as deionized water or isopropyl alcohol. The non-reactive rinse fluid could be applied by spraying, spin-rinsing, dipping, or soaking. For example, the non-reactive rinse fluid could be sprayed onto the wafer through the same or different sprayers located in the load cup of the CMP apparatus. In another example, the non-reactive rinse fluid could be sprayed onto the wafer by sprayers located on the carrier or the platen of the CMP apparatus.

Before, during, or after the fluid is applied to the polish-resistant film, the wafer is disposed within a wafer carrier. After the polish-resistant film is chemically removed from the metal layer by the fluid, but before a significant thickness of a second, subsequent polish-resistant film is permitted to form, the front surface of the wafer is contacted by a polishing surface, such as a polishing pad, of the CMP apparatus (step 1004). The surface of the wafer is pressed against the polishing surface, preferably in the presence of a polishing solution or slurry. The surface of the wafer then is planarized by generating relative motion between the surface of the wafer and the polishing surface, thereby removing metal from the metal layer on the front surface of the wafer (step 1006).

The polishing motion may be implement rotationally, linearly, or preferably, orbitally. The carrier is preferably rotated about a central axis as it presses the surface of the wafer against the polishing surface during the planarization process. The carrier may also be moved along the polishing surface to enhance the planarization process of the wafer. Because the polish-resistant film is removed before the planarization process begins, the planarization process exhibits a faster removal rate than if the polish-resistant film was not so removed. The planarization process then is continued in a conventional manner until a predetermined or desired thickness of metal is removed from the front surface of the wafer (step 1008).

By employing the above described techniques, metallization layers on semiconductor wafers can be polished on an apparatus utilizing a non-orbital platform and still achieve a substantially linear relationship between removal rate and down-force. Furthermore, acceptable removal rates can be obtained at low pressures between the polishing pad and the metal layer being polished.

In the forgoing specification, the invention has been described with reference to specific embodiments. However, it should be appreciated that various modifications and changes can be made without departing from the scope of the invention as set forth in the appended claims. Accordingly, the specification and figures should be regarded as illustrative rather than restrictive, and all such modifications are intended to be included within the scope of the present invention.

What is claimed is:

1. A method for the chemical mechanical planarization of a metal layer on a wafer, wherein the method comprises the steps of:
chemically removing at least a substantial portion of a first polish-resistant film from the metal layer;
contacting the metal layer with a polishing surface before a significant thickness of a second polish-resistant film forms on the metal layer; and
generating relative motion between the metal layer and the polishing surface.

2. The method of claim 1, wherein the step of chemically removing comprises the step of applying to the wafer a dissolution fluid that is formulated to cause dissolution of the first polish-resistant film.

3. The method of claim 2, wherein the step of applying to the wafer a dissolution fluid comprises the step of applying to the wafer a fluid comprising a material selected from the group consisting of citric acid, malonic acid, nitric acid, phosphoric acid, sulfuric acid, and oxalic acid.

4. The method of claim 3, wherein the step of applying to the wafer a dissolution fluid comprising a material selected from the group consisting of citric acid, malonic acid, nitric acid, phosphoric acid, sulfuric acid, and oxalic acid comprises the step of applying to the wafer a solution comprising about 1% to about 10% oxalic acid.

5. The method of claim 2, wherein the step of applying a dissolution fluid to the wafer comprises the step of delivering the fluid when the wafer is located in a pass-through pre-treatment stage, a loading stage, a load-cup, or a carrier of a CMP apparatus.

6. The method of claim 2, wherein the step of applying to the wafer a dissolution fluid comprises the step of spraying the fluid onto the wafer.

7. The method of claim 2, further comprising the step of heating the dissolution fluid before applying the fluid to the wafer.

8. The method of claim 7, wherein the step of heating the dissolution fluid comprises the step of heating the fluid to a temperature in the range of about 25° C. to about 70° C.

9. The method of claim 2, further comprising the step of removing the dissolution fluid from the wafer before the step of contacting the metal layer with a polishing surface.

10. The method of claim 9, wherein the step of removing the dissolution fluid from the wafer comprises the step of rinsing the dissolution fluid from the wafer with a non-reactive rinse fluid.

11. The method of claim 10, wherein the step of rinsing the dissolution fluid from the wafer with a non-reactive rinse fluid comprises the step of spraying the non-reactive rinse fluid onto the wafer through a plurality of sprayers of a load cup of a CMP apparatus, wherein the plurality of sprayers may comprise the same or different sprayers used to spray the dissolution fluid onto the wafer.

12. The method of claim 1, wherein the step of chemically removing at least a substantial portion of a first polish-resistant film from the metal layer comprises the step of chemically removing at least a substantial portion of a first polish-resistant film from the metal layer comprising at least one metal selected from the group consisting of copper, tungsten, aluminum, cobalt, tantalum, tantalum nitride, titanium, titanium nitride, silver, gold, and ruthenium.

13. A method for the chemical mechanical planarization of a metal layer on a wafer, wherein a surface of the metal layer comprises a first polish-resistant film, and wherein the method comprises the steps of:
applying a fluid to at least substantially cover the surface of the metal layer, wherein the fluid is formulated for dissolution of at least a substantial portion of the first polish-resistant film from the metal layer;
initiating chemical mechanical planarization of the metal layer before a significant thickness of a second polish-resistant film forms on the metal layer; and
continuing chemical mechanical planarization until a predetermined thickness of the metal layer is removed from the wafer.

14. The method of claim 13, wherein the step of applying a fluid to at least substantially cover the surface of the metal layer comprises the step of applying a fluid to at least substantially cover the surface of the metal layer comprising at least one metal selected from the group consisting of copper, tungsten, aluminum, cobalt, tantalum, tantalum nitride, titanium, titanium nitride, silver, gold, and ruthenium.

15. The method of claim 13, wherein the step of applying a fluid to at least substantially cover the surface of the metal layer comprises the step of applying a fluid comprising a material selected from the group consisting of citric acid, malonic acid, nitric acid, phosphoric acid, sulfuric acid, and oxalic acid.

16. The method of claim 13, wherein the step of applying a fluid comprises the step of spraying the fluid.

17. The method of claim 13, further comprising the step of permitting about 5 to about 60 seconds to pass between the step of applying a fluid and the step of initiating chemical mechanical planarization.

18. The method of claim 13, further comprising the step of heating the fluid before the step of applying the fluid.

19. The method of claim 13, wherein the step of applying a fluid comprises the step of delivering the fluid when the wafer is located in a pass-through pre-treatment stage, a loading stage, a load-cup, or a carrier of a CMP apparatus.

20. A method for polishing a metallized surface on a workpiece, said metallized surface having a polish-resistant film thereon, said method comprising the steps of:
sputtering said metallized surface to substantially remove said film; and
polishing said metallized surface by creating relative motion between said metallized surface and a polishing surface at a first pressure in the presence of a substantially non-abrasive polishing solution.

21. A method of claim 20, wherein the step of polishing comprises the step of polishing at a first pressure substantially between 0.1 psi and 3.0 psi.

22. The method of claim 20, wherein the step of sputtering comprises the step of sputtering in an argon chamber.
